(19) United States
(12) Patent Application Publication
(10) Pub. No.: US 2022/0301785 A1
(43) Pub. Date: Sep. 22, 2022

(54) ANTIFERROELECTRIC CAPACITOR

(71) Applicants: HERMES-EPITEK CORPORATION, Taipei City (TW); National Taiwan University, Taipei (TW)

(72) Inventors: Miin-Jang Chen, Taipei City (TW); Sheng-Han Yi, Taipei City (TW); Jih-Jenn Huang, Hsinchu City (TW)

(21) Appl. No.: 17/583,868

(22) Filed: Jan. 25, 2022

Related U.S. Application Data
(60) Provisional application No. 63/162,703, filed on Mar. 18, 2021.

(51) Int. Cl. H01G 7/06

(52) U.S. Cl. CPC H01G 7/06

(57) ABSTRACT

In this disclosure, antiferroelectric capacitors having one or more interfacial layer/antiferroelectric layer/interfacial layer stacked structures are proposed. The compressive chemical pressure of the proposed structure leads to a reduction of the hysteresis and thus a high ESD and a low energy loss. A provided antiferroelectric capacitor demonstrates a record-high ESD of 94 J/cm³ and a high efficiency of 80%, along with a high maximum power density of 5×10¹⁰ W/kg. The degradation of the energy storage performance as the film thickness increases is alleviated by the above multi-stacked structure, which presents a high ESD of 80 J/cm³ and efficiency of 82% with the thickness scaled up to 48 nm. This improvement is attributed to the enhancement of breakdown strength due to the barrier effect of interfaces on electrical treeing. Furthermore, the capacitors also exhibit an excellent endurance up to 10¹⁰ operation cycles.

### CROSS-REFERENCE TO RELATED APPLICATIONS

This application claims the priority benefit of U.S. provisional application Ser. No. 63/162,703, filed on Mar. 18, 2021. The entirety of the above-mentioned patent application is herein expressly incorporated by reference and made a part of specification.

### BACKGROUND OF THE INVENTION

### 1. Field of the Invention

The present invention relates to an antiferroelectric capacitor with ultra-high energy storage density and scalability.

### 2. Description of Related Art

In recent years, with the ever-increasing of worldwide energy consumption and the rapid development of renewable energy resources, the demand for efficient and reliable energy storage systems has grown substantially. ¹ Among various energy storage technologies, solid-state dielectric capacitors possess high charge/discharge rates and high power densities compared to lithium-ion batteries and electrochemical capacitors.² Hence solid-state dielectric capacitors are particularly suitable for high-power and pulsed-power electronic devices, including hybrid electric vehicles, medical equipment, avionics, military weapons,³⁻⁵ etc. Among various dielectrics, antiferroelectric (AFE) materials are characterized with a reversible phase transition between an anti-polar AFE phase and a polar ferroelectric (FE) phase upon the application and removal of an external electric field. This distinguishing feature enables AFE materials to build up a large amount of energy when being charged, compared to linear dielectrics, and to experience small energy loss upon discharging, compared to FE materials.⁶ Therefore, AFE materials are much favorable for energy storage capacitors.

Conventional perovskite-structured AFE oxides, such as lead zirconate (PZ)-based materials, are widely regarded as the candidates for electrostatic energy storage.^{6,7} However, they suffer from low breakdown field, poor reliability, and lead-contamination.⁸ In this decade, AFE-like characteristics have been observed in the HfO₂/ZrO₂-based thin films due to the phase transformation from the non-polar tetragonal (t-) (space group: P4₂/nmc) phase to the FE orthorhombic (space group: Pca2₁) crystalline structure as an external electric field is applied.⁹⁻¹¹ High energy storage capacity comparable or even superior to conventional perovskite materials has been achieved in the HfO₂/ZrO₂-based thin films.² In addition, HfO₂/ZrO₂-based thin films are environmentally friendly and highly compatible with the processing in advanced semiconductor technology nodes. As a result, the AFE HfO₂/ZrO₂-based thin films have been recognized as a high potential candidate to replace the conventional perovskite AFE materials in energy storage applications. Furthermore, since the thickness of the HfO₂/ZrO₂-based AFE thin films is scalable down to ˜10 nm, they are particularly suitable for the energy storage nanocapacitors in miniaturized energy-autonomous systems and embedded portable/wearable electronics.¹²

Energy storage density (ESD) and energy storage efficiency are the most important figures of merit for energy storage capacitors. However, there seems to be a compromise between the ESD and the efficiency. For AFE HfO₂/ZrO₂-based thin films so far reported in the literature, the maximal ESD was 60 J/cm³ while with a fair efficiency of 60%,¹³ whereas the maximal efficiency of 93% was accompanied with a low ESD of only 22 J/cm³.¹⁴ As a result, there is still room for improvement of both the ESD and the efficiency of AFE HfO2/ZrO₂-based thin films. In addition, further enhancement of ESD of solid-state dielectric capacitors will expand the field of energy storage applications in which the electrochemical supercapacitors and batteries are typically used.

In order to increase the total stored energy, the film thickness of dielectric capacitors needs to be scaled up.¹⁷ However, studies have shown that an increase of the thickness of HfO₂/ZrO₂-based thin films results in the formation of the non-AFE monoclinic phase (space group: P2₁/c), which deteriorates the AFE characteristics.^{8,17} Thus the energy storage performance is drastically degraded with an increase in the thickness of the HfO₂/ZrO₂-based thin films.^{8,17} On the other hand, it has been reported that TiO₂ interfacial layers enhance the antiferroelectricity of ZrO₂ thin films in the inventors' previous study.¹⁸

References: [1]. L. Yang, X. Kong, F. Li, H. Hao, Z. Cheng, H. Liu, J.-F. Li and S. Zhang, Prog. Mater Sci., 2019, 102, 72-108; [2] H. Palneedi, M. Peddigari, G.-T. Hwang, D.-Y. Jeong and J. Ryu, Adv. Funct. Mater., 2018, 28, 1803665; [3] R. W. Johnson, J. L. Evans, P. Jacobsen, J. R. Thompson and M. Christopher, IEEE Trans. Compon. Packag. Manuf. Technol., 2004, 27, 164-176; [4] F. W. MacDougall, J. B. Ennis, R. A. Cooper, J. Bates and K. Seal, 14th IEEE Int. Pulsed Power Conf., 2003,1, pp. 513-517 Vol.511; [5] J. A. Weimer, AIAA/IEEE Digital Avionics Systems Conf., 1993, 283509, pp. 445-450; [6] Z. Liu, T. Lu, J. Ye, G. Wang, X. Dong, R. Withers and Y. Liu, Adv. Mater. Technol, 2018, 3, 1800111; [7] A. Chauhan, S. Patel, R. Vaish and C. R. Bowen, Materials, 2015, 8, 8009-8031; [8] M. H. Park, H. J. Kim, Y. J. Kim, T. Moon, K. D. Kim and C. S. Hwang, Adv. Energy Mater, 2014, 4, 1400610; [9] T. Böscke, J. Müller, D. Bräuhaus, U. Schröder and U. Böttger, Appl. Phys. Lett., 2011, 99, 102903; [10] J. Muller, T. S. Boscke, U. Schroder, S. Mueller, D. Brauhaus, U. Bottger, L. Frey and T. Mikolajick, Nano Lett., 2012, 12, 4318-4323; [11] S. E. Reyes-Lillo, K. F. Garrity and K. M. Rabe, Phys. Rev. B, 2014, 90, 140103; [12] F. Ali, D. Zhou, N. Sun, H. W. Ali, A. Abbas, F. Iqbal, F. Dong and K.-H. Kim, ACS Appl. Energy Mater, 2020, 3, 6036-6055; [13]F. Ali, X, Liu, D. Zhou, X. Yang, J. Xu, T. Schenk, J. Müller, U. Schroeder, F. Cao and X. Dong, J. Appl. Phys., 2017, 122, 144105; [14]P. D. Lomenzo, C.-C. Chung, C. Zhou, J. L. Jones and T. Nishida, Appl. Phys. Lett., 2017, 110, 232904; [15] M. Pes̆ić, M. Hoffmann, C. Richter, T. Mikolajick and U. Schroeder, Adv. Funct. Mater., 2016, 26, 7486-7494; [16] K. Kühnel, M. Czernohorsky, C. Mart and W. Weinreich, J. Vac. Sci. Technol. B, 2019, 37, 021401; [17] K. D. Kim, Y H. Lee, T. Gwon, Y. J. Kim, H. J. Kim, T. Moon, S. D. Hyun, H. W. Park, M. H. Park and C. S. Hwang, Nano Energy, 2017, 39, 390-399; [18] S.-H. Yi, B.-T. Lin, T.-Y. Hsu, J. Shieh and M.-J. Chen, J. Eur. Ceram. Soc., 2019, 39, 4038-4045; [19] Z. Sun, C. Ma, M. Liu, J. Cui, L. Lu, J. Lu, X. Lou, L. Jin, H. Wang and C.-L. Jia, Adv. Mater , 2017, 29, 1604427; [20] C. Hou, W. Huang, W. Zhao, D. Zhang, Y. Yin and X. Li, ACS Appl. Mater. Interfaces, 2017, 9, 20484-20490; [21] H. Pan, J. Ma, J. Ma, Q. Zhang, X. Liu, B. Guan, L. Gu, X. Zhang, Y.-J. Zhang, L. Li, Y. Shen, Y.-H. Lin and C.-W. Nan, Nat. Commun., 2018, 9, 1813; [22] K. Wu, Y. Wang, Y. Cheng, L. A. Dissado and X. Liu, J. Appl. Phys., 2010, 107, 064107; [23] S. Li, H. Nie, G. Wang, C. Xu, N. Liu, M. Zhou, F. Cao and X. Dong, J. Mater. Chem. C, 2019, 7, 1551-1560; [24] H. Kawamura and K. Azuma, J. Phys. Soc. Jpn., 1953, 8, 797-798; [25] International Centre for Diffraction Data (2003) PDF-2. ICDD, Newtown Square; [26] L. Kong, I. Karatchevtseva, H. Zhu, M. J. Qin and Z. Aly, J. Mater. Sci. Technol., 2019, 35, 1966-1976; [27] M. K. Jain, M. C. Bhatnagar and G. L. Sharma, Jpn. J. Appl. Phys., 2000, 39, 345-350; [28] R. Materlik, C. Künneth and A. Kersch, J. Appl. Phys., 2015, 117, 134109; [29] H. Miura, H. Ohta, N. Okamoto and T. Kaga, Appl. Phys. Lett., 1992, 60, 2746-2748; [30]W. Weinreich, L. Wilde, J. Müller, J. Sundqvist, E. Erben, J. Heitmann, M. Lemberger and J. Bauer, Journal of Vacuum Science & Technology A, 2013, 31, 01A119; [31]W. D. Nix and B. M. Clemens, J. Mater. Res., 1999, 14, 3467-3473; [32] P. Chandra and P. B. Littlewood, in Physics of Ferroelectrics: A Modern Perspective, Springer Berlin Heidelberg, Berlin, Heidelberg, 2007, DOI: 10.1007/978-3-540-34591-6_3, pp. 69-116; [33] H. Cai, S. Yan, M. Zhou, N. Liu, J. Ye, S. Li, F. Cao, X. Dong and G. Wang, J. Eur. Ceram. Soc., 2019, 39, 4761-4769; [34] R. Yimnirun, P. J. Moses, R. E. Newnham and R. J. Meyer, J. Electroceram., 2002, 8, 7-98; [35] S. Yoneda, T. Hosokura, M. Kimura, A. Ando and K. Shiratsuyu, Jpn. J. Appl. Phys., 2017, 56, 10PF07; [36] M. Hoffmann, U. Schroeder, C. Künneth, A. Kersch, S. Starschich, U. Böttger and T. ikolajick, Nano Energy, 2015, 18, 154-164; [37] M. G. Kozodaev, A. G. Chernikova, R. R. Khakimov, M. H. Park, A. M. Markeev and C. S. Hwang, Appl. Phys. Lett., 2018, 113, 123902; [38] D. Ceresoli and D. Vanderbilt, Phys. Rev. B, 2006, 74, 125108; [39] S. J. Kim, J. Mohan, J. S. Lee, H. S. Kim, J. Lee, C. D. Young, L. Colombo, S. R. Summerfelt, T. San and J. Kim, ACS Appl. Mater. Interfaces, 2019, 11, 5208-5214; [40] C. Yang, P. Lv, J. Qian, Y. Han, J. Ouyang, X. Lin, S. Huang and Z. Cheng, Adv. Energy Mater, 2019, 9, 1803949; [41]P. Lv, C. Yang, J. Qian, H. Wu, S. Huang, X. Cheng and Z. Cheng, Adv. Energy Mater, 2020, 10, 1904229; [42]Y. Fan, Z. Zhou, Y. Chen, W. Huang and X. Dong, J. Mater. Chem. C, 2020, 8, 50-57; [43] Q. Fan, M. Liu, C. Ma, L. Wang, S. Ren, L. Lu, X. Lou and C.-L. Jia, Nano Energy, 2018, 51, 539-545; [44] X. Chen, B. Peng, M. Ding, X. Zhang, B. Xie, T. Mo, Q. Zhang, P. Yu and Z. L. Wang, Nano Energy, 2020, 78, 105390; [45]T. Zhang, W. Li, Y. Zhao, Y Yu and W. Fei, Adv. Funct. Mater., 2018, 28, 1706211; [46] B. Ma, Z. Hu, R. E. Koritala, T. H. Lee, S. E. Dorris and U. Balachandran, J. Mater. Sci.: Mater. Electron., 2015, 26, 9279-9287; [47] Y. Z. Li, J. L. Lin, Y. Bai, Y. Li, Z. D. Zhang and Z. J. Wang, ACS Nano, 2020, 14, 6857-6865; [48] Z. Xie, Z. Yue, B. Peng, J. Zhang, C. Zhao, X. Zhang, G. Ruehl and L. Li, Appl. Phys. Lett., 2015, 106, 202901; [49] R. Kötz and M. Carlen, Electrochim. Acta, 2000, 45, 2483-2498; [50] W. Raza, F. Ali, N. Raza, Y. Luo, K.-H. Kim, J. Yang, S. Kumar, A. Mehmood and E. E. Kwon, Nano Energy, 2018, 52, 441-473.

### SUMMARY OF THE INVENTION

In an aspect of this invention, an antiferroelectric capacitor is provided with a first electrode, a main layer formed on the first electrode, and a second electrode formed on the main layer. The main layer preferably includes one or more antiferroelectric layers and a plurality of interfacial layers, where each antiferroelectric layer is sandwiched between two of the interfacial layers.

In examples of this invention, AFE dielectric capacitors consisting of interfacial layer/antiferroelectric layer/interfacial layer stacked structure are proposed and investigated to achieve an ultrahigh ESD with a decent efficiency. In addition, the present disclosure demonstrates that the structure can be scaled up with insignificant reduction of the ESD and the efficiency. The introduction of the interfacial layer between two antiferroelectric layers alleviates the decrease in the electrical breakdown field as the film thickness increases. In some embodiments, the interdiffusion between the interfacial layer and the adjacent antiferroelectric layer leads to the compressive stress in the antiferroelectric layers, as revealed by the XRD analyses, which results in a slim AFE hysteresis loop according to the Landau theory and thus the improved energy storage properties. Moreover, the AFE dielectric capacitor also presents an excellent fatigue resistance and robust thermal stability, along with a high power density and a high discharge speed. All of the results demonstrate that the interfacial layer engineering can be an effective approach to enhance the energy storage performance of the antiferroelectric capacitor.

### BRIEF DESCRIPTION OF THE DRAWINGS

FIG. 1 is a schematic cross-sectional view showing an antiferroelectric capacitor in accordance with an embodiment of this invention.

FIG. 2 shows a schematic illustration of the energy storage density (ESD) and the energy loss in a P-E loop of AFE materials.

FIG. 3A show Weibull distribution plots of the dielectric breakdown strength of the ZO and TZTn samples in accordance with embodiments of this invention.

FIG. 3B show evolution of the breakdown strength of the ZO and TZTn samples with the thickness of the main layer.

FIGS. 4A and 4B respectively show the evolution of the unipolar P-E curve of the ZO and TZTn capacitors with the increasing thickness of the main layer.

FIGS. 5A, 5B, and 5C respectively show the ESD, the efficiency, and total stored energy of the of the ZO and TZTn capacitors obtained from the P-E curves of FIGS. 4A and 4B.

FIG. 6A shows the out-of-plane θ/2θ XRD patterns (20° to 80°) of the ZO samples with the main layer thickness from ˜8.7 to ˜48 nm.

FIG. 6B shows the out-of-plane θ/2θ XRD patterns (33° to 38°) of the ZO samples with the main layer thickness from ˜8.7 to ˜48 nm.

FIG. 7A shows the out-of-plane θ/2θ XRD patterns (20° to80°) of the TZTn samples with the main layer thickness from ˜8.7 to ˜48 nm.

FIG. 7B shows the out-of-plane θ/2θ XRD patterns (33° to 38°) of the TZTn samples with the main layer thickness from ˜8.7 to ˜48 nm.

FIG. 8A shows in-plane 2θχ/ϕ XRD patterns of the ZO(48 nm) and TZT7 samples with the 2θχ/ϕ XRD ranging from 25° to 80°.

FIG. 8B shows in-plane 2θχ/ϕ XRD patterns of the ZO(48 nm) and TZT7 samples with the 2θχ/ϕ XRD ranging from 32° to 38°.

FIGS. 9A and 9B show phenomenological energy landscapes of AFE materials with and without the presence of compressive stress and the corresponding P-E characteristics, respectively.

FIG. 10A and 10B respectively show the evolution of the ESD and the efficiency of the TZT1 and TZT7 samples versus the charging-discharge operation cycles.

FIGS. 11A and 11B respectively show P-E characteristics and the ESD and the efficiency of the TZT1 capacitor versus temperature from 25° C. to 150° C.

FIGS. 12A-C show the evolution of the discharging current I, the power density, and the ESD and ESD percentage of the TZT1 capacitor over time, respectively.

FIG. 13 show comparison of the ESD and the efficiency of the TZTn capacitors in this invention with those of HfO2/ZrO₂-based AFE and representative lead-free/lead-based dielectric films reported from the literature.

FIGS. 14A and 14B show the XPS depth profiles of the elements (Zr, Ti, O, and Pt) and the depth profile of the Ti/[Zr+Ti] percentage in the TZT2 sample, respectively.

FIGS. 15A and 15B respectively show evolution of the P-E curves of the TZT1 and TZT7 capacitors with the fatigue cycling of unipolar rectangular pulses.

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention.

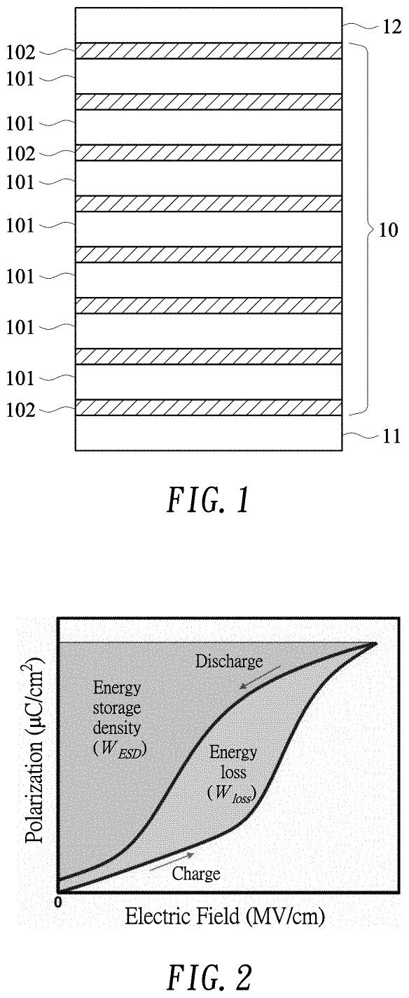

FIG. 1 is a schematic cross-sectional view showing an antiferroelectric capacitor in accordance with an embodiment of this invention. Referring to FIG. 1, the antiferroelectric capacitor includes a first electrode 11, a main layer 10 formed on the first electrode 11, and a second electrode 12 formed on the main layer 10. The main layer 10 preferably includes one or more antiferroelectric layers 101 and a plurality of interfacial layers 102, where each antiferroelectric layer 101 is sandwiched between two of the plurality of interfacial layers 102. The number of the one or more antiferroelectric layers 101 is n, and the number of the interfacial layers 102 is n+1, where n is a positive integer, e.g., 1, 2, 3, 4, 5, 6, 7, 8, 9, 10, and so on. In the exemplary embodiment, the main layer 10 includes, but is not limited to, seven antiferroelectric layers 101 and eight interfacial layers 102.

Referring to FIG. 1, each antiferroelectric layer 101 is made of a material selected from the group consisting of ZrO₂, HfO₂, and HfₓZr₁₋O₂, where x denotes a fraction. In some embodiments, each antiferroelectric layer 101 made of ZrO₂, HfO₂, or HfₓZr₁₋O₂ may be further doped with one or more elements selected from the group consisting of Si, Y, Al, La, Gd, N, Ti, Mg, Sr, Ce, Sn, Ge, Fe, Ta, Ba, Ga, In, Sc, and the like. In addition, each interfacial layer 102 may be made of an oxide of Si, Y, Al, La, Gd, N, Ti, Mg, Sr, Ce, Sn, Ge, Fe, Ta, Ba, Ga, In, Sc, or the like. The first electrode 11 and the second electrode 12 are typically made of a metal or a conductive material and may have other configurations without being limited to the form of a layer. The antiferroelectric capacitor may be formed on a substrate. In some embodiments, the first electrode 11 and the second electrode 12 are made of a conductive material selected from the group consisting of Pt, W, TiN, Ti, Ir, Ru, RuOx, Cr, Ni, Au, Ag, and Al.

Referring to FIG. 1, physical or chemical processes, e.g., sputtering, chemical vapor deposition, metal-organic chemical vapor deposition (MOCVD), or atomic layer deposition (ALD), may be utilized to fabricate the first electrode 11, the main layer 10, and the second electrode 12.

Referring to FIG. 1, in some embodiments, an interdiffusion may occur between the antiferroelectric layers and the adjacent interfacial layers during a fabrication process of the antiferroelectric capacitor. In some embodiments, a compressive strain along the out-of-plain direction of the antiferroelectric capacitor is kept when the thickness of the main layer is scaled up. In some embodiments, the compressive strain in the out-of-plane direction is larger than that in the in-plane direction of the antiferroelectric capacitor. In some embodiments, an in-plane biaxial tensile stress exists in the main layer 10.

In some embodiments, an efficiency of the provided antiferroelectric capacitor is more than 80%. In some embodiments, the efficiency keeps at more than 80% when a temperature of the antiferroelectric capacitor increases to 150° C. In some embodiments, the efficiency keeps at more than 80% after 10¹⁰ cycles of unipolar pulses applied to the antiferroelectric capacitor.

In some embodiments, the provided antiferroelectric capacitor has an energy storage density (ESD) more than 80 J/cm³. In some embodiments, the energy storage density (ESD) is about 90 J/cm³. In some embodiments, the energy storage density (ESD) keeps at about 90 J/cm³ when a temperature of the antiferroelectric capacitor increases to 150° C. In some embodiments, the energy storage density (ESD) keeps at about 90 J/cm³ after 10¹⁰ cycles of unipolar pulses applied to the antiferroelectric capacitor.

In the following examples, specific materials ZrO₂ and TiO₂ are selected to form the antiferroelectric layers 101 and the interfacial layers 102, respectively, to investigate the properties of the antiferroelectric capacitor. Two metal-insulator-metal (MIM) structures, denoted as the ZO and TZTn (where n is a positive integer) samples, were fabricated on a silicon substrate to investigate the energy storage properties of the AFE TiO₂/ZrO₂/TiO₂ stacks. In the ZO sample, the main layer 10 includes a ZrO₂ antiferroelectric layer sandwiched between two TiO₂ interfacial layers. In the TZTn sample, the main layer 10 includes n ZrO₂ antiferroelectric layer(s) 101 and n+1 TiO₂ interfacial layers 102, where each ZrO₂ antiferroelectric layer 101 is sandwiched between two of the TiO₂ interfacial layers 102, and n is a positive integer from 1 to 7. In addition, a bottom Pt electrode and a top Pt electrode are respectively deposited below and above the main layer in both the ZO sample and the TZTn samples.

An exemplary fabrication process is described as follows. A TiO₂ layer is deposited on a silicon substrate. A bottom Pt electrode (˜100 nm in thickness) was then deposited on the TiO₂ layer by sputtering, where the TiO₂ layer serves as an adherence layer for the overlying bottom Pt electrode. Nanoscale ZrO₂ and TiO₂ thin films in the dielectric main layer of the MIM structures were deposited on the bottom Pt electrode by remote plasma atomic layer deposition at 250° C. Tetrakis(dimethylamino)titanium (Ti[N(CH₃)₂]₄), Tetrakis-(dimethylamino)zirconium (Zr[N(CH₃)₂]₄), and oxygen plasma were the precursors and the reactant for Ti, Zr, and O, respectively. In the main layer of the ZO samples, a ZrO₂ layer was prepared with a thickness ranging from 8.7 to 48 nm, and TiO₂ interfacial layers were introduced between the ZrO₂ layer and the top/bottom Pt electrodes to facilitate the formation of the AFE t-phase in ZrO₂ according to the inventors' previous study.¹⁸ On the other hand, the main layer in the TZTn samples comprises the TiO₂/ZrO₂/TiO₂ multi-stacks, where n is the number of the stacks. The TiO₂ interfacial layer was introduced to enhance the electrical breakdown field as the film is scaled up due to the suppression of the development of electrical trees.^{19,20} The ZrO₂ thickness in each TiO₂/ZrO₂/TiO₂ stack is ˜6 nm. The TiO₂ interfacial layers in the ZO and TZTn samples were deposited with 15 ALD cycles. A top Pt electrode (˜100 nm in thickness) was then deposited on the main layer of the ZO and TZTn samples, respectively, by sputtering. High-angle annular dark-field (HAADF) images and the energy-dispersive X-ray spectroscopy (EDS) elemental mapping of the cross-sectional profiles of the ZO(48 nm) and TZT7 samples are obtained, respectively. The Z-contrast can be clearly observed in the HAADF images as the brightness of the TiO₂, ZrO₂, and Pt layers appear in ascending order in accord with their atomic numbers. The EDS images also present distinguishable TiO₂ interfacial layers at the interfaces of the top/bottom Pt electrodes. Interleaving TiO₂ and ZrO₂ structure can be observed in the TZT7 sample. Afterward, the optical lithography and lift-off processes were used to define the top circular Pt electrode with a radius of 100 μm. All the samples were processed with a post-metallization annealing treatment at 500° C. in N₂ ambient for 30 s using rapid thermal annealing.

Scanning transmission electron microscopy (STEM) and EDS mapping of the samples were carried out by a field-emission transmission electron microscope (Talos F200XG2, FEI) operated at 200 kV equipped with a superX EDS system with four silicon drift detectors. The out-of-plane (θ/2θ) and in-plane (2θχ/ϕ) XRD measurements were performed using an X-ray diffractometer (TTRAX III, Rigaku) with Cu-Kα radiation (λ=0.154 nm). Polarization-electric field (P-E) loops of the TiO₂/ZrO₂/TiO₂ stacks were probed by a unipolar triangular voltage excitation at a frequency of 1 kHz using a Keithley 4200 semiconductor characterization system. Dielectric breakdown strengths were characterized using an Agilent B1500A semiconductor device parameter analyzer.

Results and Discussion

Before analyzing the experimental results, the strategy for the enhancement of energy storage density and efficiency in dielectric capacitors are discussed. As illustrated in the AFE P-E loop in FIG. 2, the ESD (WES_{D}) and the energy loss (Wₗₒₛₛ) can be calculated by the integration of electric field over polarization during the discharge and the full charge-discharge loop of the capacitor, respectively:

$${W}_{E S D} = {\int }_{{P}_{r}}^{{P}_{max}} EdP ( upon discharging ) \qquad ( 1 )$$

$${W}_{l o s s} = ∮ Edp ( upon charging ) - {W}_{ESD} \qquad ( 2 )$$

where E, P, Pᵣ and Pₘₐₓ are the electric field, polarization, remnant polarization, and polarization at the maximal applied electric field, respectively. The ESD is equal to the area enclosed by P-E curve upon the removal of electric field. The hysteresis loop indicates the energy loss during the charge-discharge period. Hence the efficiency of the energy storage device is defined as follows:

$$Efficiency = \frac{{W}_{ESD}}{{W}_{ESD} + {W}_{loss}} \times 100 \% \qquad ( 3 )$$

It should be noted that the ESD increases with the electrical breakdown field. Moreover, a reduction of the hysteresis loop not only leads to an increase in efficiency but also an enhancement of ESD. A higher efficiency means a lower waste heat generation due to the energy loss during the charge-discharge process, giving rise to improved reliability and a longer lifetime of the devices.²¹ As a result, an increase of the dielectric breakdown strength and a suppression of the hysteresis loop would be a good strategy to enhance the ESD and the efficiency of the AFE capacitor. Apart from the enhancement of the AFE properties of ZrO₂ by the TiO₂ interfacial layers as demonstrated in our previous work,¹⁸ the purpose of introducing the TiO₂ interfacial layers between the ZrO₂ layers is to create the interfaces that can hinder the spreading of electrical trees and thus enhance the dielectric breakdown field as the film thickness increases.^{19,20} Furthermore, as discussed in the following, the TiO₂ interfacial layers between the ZrO₂ layers induce compressive stress due to the doping of Ti into ZrO₂, which reduces the hysteresis and thus improves the energy storage performance.

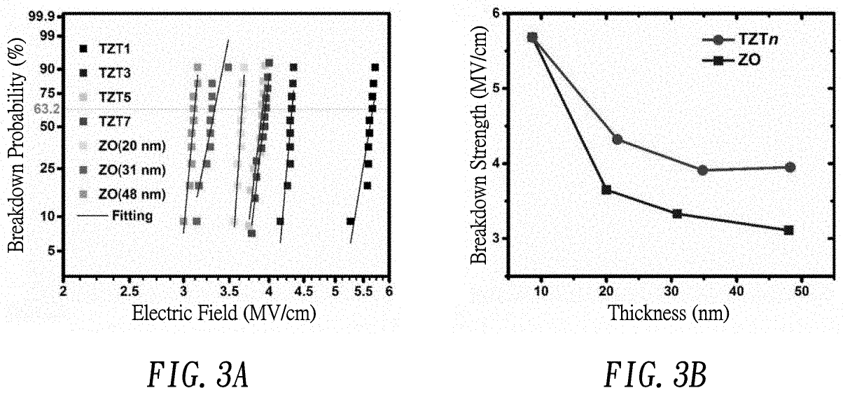

FIG. 3A shows the Weibull plot of the dielectric breakdown strength of the ZO and TZTn capacitors. The dielectric breakdown strength of the dielectric layers can be extracted by analyzing the Weibull distribution function described by:

$$P ( {E}_{i} ) = 1 - exp ( - {( \frac{{E}_{i}}{{E}_{b}} )}^{β} ) \qquad ( 4 )$$

where P(Eᵢ) is the cumulative probability, Eᵢ is the electrical breakdown field of the tested sample arranged in ascending order, E_{b} is the characteristic breakdown strength corresponding to the cumulative breakdown probability of 63.2% of the tested devices, and β is the Weibull modulus that describes the variation of dielectric breakdown.^{22,23} Each Eᵢ was obtained by applying an increasing DC voltage to the capacitor until the dielectric breakdown occurred. Equation (4) can be rearranged by taking logarithms as follows:

ln[−ln(1−P(Eᵢ))]=β[ln(Eᵢ)−ln(E_{b})] (5)

As a result, the dielectric breakdown strength can be extracted by linear fitting of the Yᵢ=ln[−ln(1−P(Eᵢ))] versus ln(Eᵢ) plot, and the E_{b} can be given by the intercept at Y=0. FIG. 3B plots the dependence of the characteristic breakdown strength E_{b} on the thickness of the main layer in the ZO and TZTn capacitors. The decrease of the breakdown strength with the increasing thickness in both samples can be understood from the increase of the electron collisions, which would lead to impact ionization and thus avalanche breakdown of the films ²⁴. The result demonstrates that the breakdown strength of the TZTn capacitors with the TiO₂ interfacial layers between the ZrO₂ layers is higher than that of the ZO samples without the TiO₂ interfacial layers between the ZrO₂ layers as the film thickness is scaled up. Hence the TiO₂ interfacial layers between the ZrO₂ layers contribute to the enhancement of dielectric breakdown strength. This can be attributed to the presence of the ZrO₂/TiO₂ interfaces, which suppresses the growth of electrical trees.^{19,20}

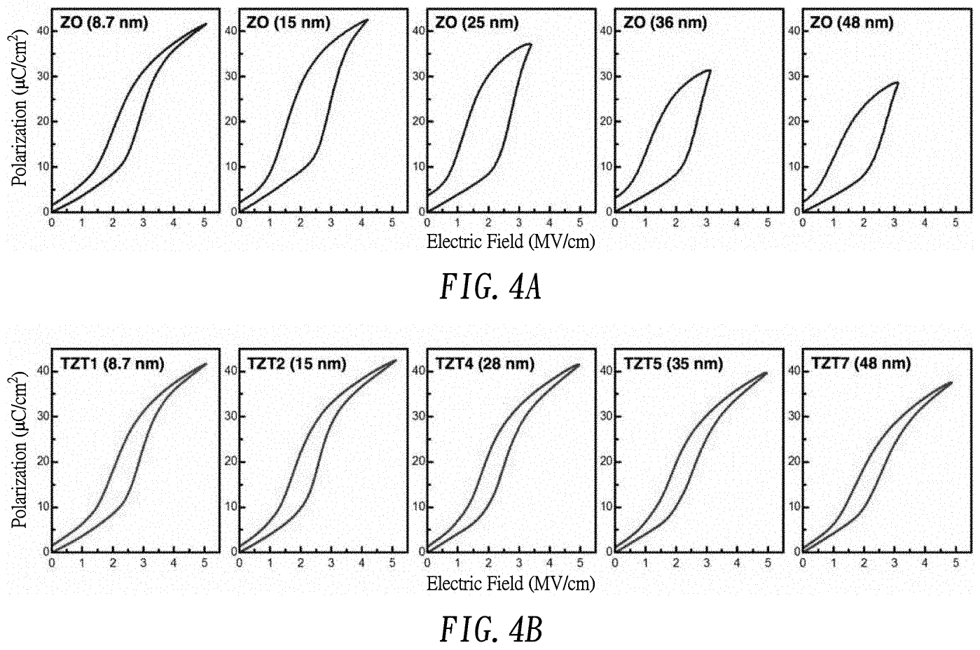

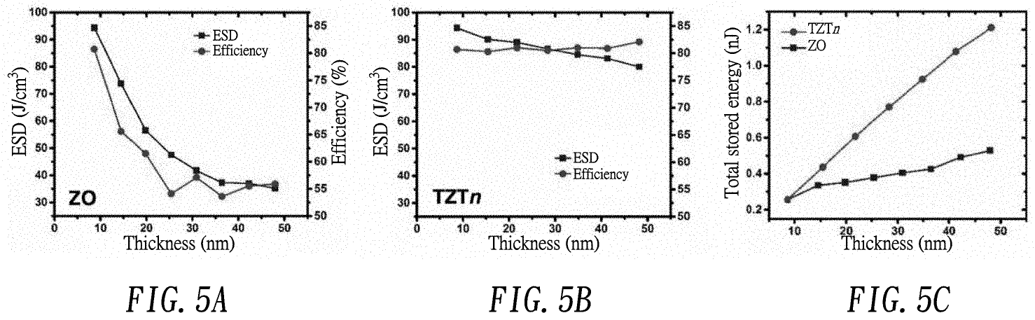

FIGS. 4A and 4B respectively show the evolution of the unipolar P-E curve of the ZO and TZTn capacitors with the increasing thickness of the main layer. It can be observed that the hysteresis loop of the ZO samples becomes wider as the main layer thickness increases. On the other hand, the TZTn capacitors show rather slim hysteresis loops when the main layer thickness is scaled up. The ESD and the efficiency obtained by the P-E curves are shown in FIGS. 5A-B. FIG. 5A reveals that both the ESD and the efficiency of the ZO samples decrease significantly from 94 to 35 J/cm³ and 80 to 56%, respectively, as the thickness increases from 8.7 to 48 nm. On the other hand, FIG. 5B shows that the TZTn capacitors only present minor reduction of ESD from 94 to 80 J/cm³ and little variation of efficiency in the range between 80 and 82% when the main layer is scaled up to 48 nm. A high ESD up to ˜94 J/cm³ was achieved in the ZO(8.7 nm)/TZT1 samples under a maximum electric field of 5 MV/cm. Notice that the layer structures of the ZO(8.7 nm) and TZT1 samples are identical. FIG. 5C shows the total energy storage of the ZO and TZT capacitors as a function of the film thickness. With increasing the film thickness, the total energy storage of the TZT samples increases much more than that of the ZO sample. Since the scale-up of capacitors can increase the energy storage capacity and the operation voltage, the scalability of the TZTn structure would contribute to being flexible and advantageous for practical use in different applications. It is thus demonstrated that the TiO₂ interfacial layers between the ZrO₂ layers can effectively facilitate the performance of energy storage during scaling up, which is ascribed to the enhancement of breakdown strength and the suppression of hysteretic behavior.

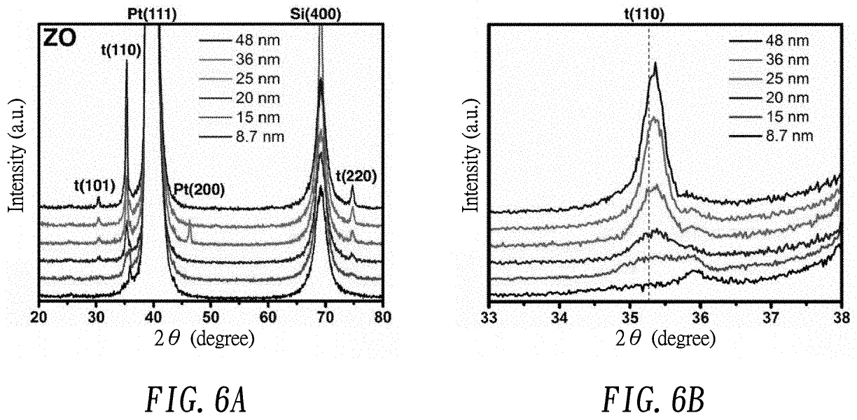

To explain the reduced hysteresis and thus the higher ESD and efficiency of the TZTn capacitors (as compared with the ZO samples) in terms of microstructures, an XRD analysis was carried out. The out-of-plane θ/2θ XRD patterns of the ZO samples with the main layer thickness from ˜8.7 to ˜48 nm are shown in FIGS. 6A and 6B. FIG. 6A shows the XRD patterns in a wide 2θ range from 20 to 80°. It can be observed that a strong diffraction peak from ZrO₂ is present around 35°, which indicates the preferred orientation of the ZrO₂ layer. The XRD patterns in a narrow 2θ range from 33° to 38 ° are shown in FIG. 6(b), in which the diffraction peaks in the range between 35° and 36° can be ascribed to the (110) plane of the t-phase, which is widely recognized as the origin of the AFE behaviors in ZrO₂ thin films.^{10,11} For the ZO(8.5 nm) sample, the shift of the diffraction peak from the reference t(110) peak at 35.27° (referenced from PDF #79-1769)²⁵ toward a higher angle at ˜36° indicates the presence of the compressive strain along the out-of-plain direction. With an increase in the thickness of the main layer, the diffraction peaks gradually shift from 36° to 35.4°, revealing that the compressive strain is gradually relaxed when the thickness exceeds 20 nm in the ZO samples.

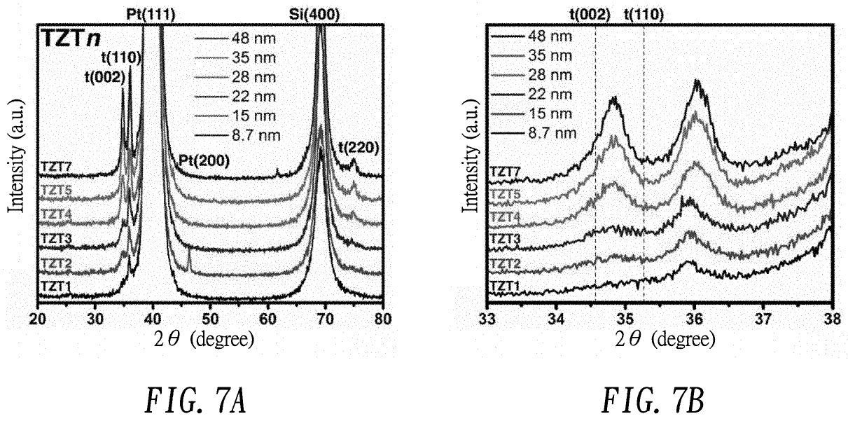

FIGS. 7A and 7B show the out-of-plane θ/2θ XRD patterns of the TZTn samples, in which the thickness of the main layer ranges from ˜8.7 to ˜48 nm. Two strong peaks from ZrO₂ around 35° and 36° can be observed in the wide- and narrow-range XRD patterns (FIG. 7A and 7B), which can be attributed to the diffraction from the (002) and (110) planes of the t-phase. The t(002) and t(110) diffraction peaks of the TZTn samples remain deviated from the referenced t(002) and t(110) peaks at 34.57° and 35.27° to the high angles at ˜35° and ˜36° as the number of the TiO₂/ZrO₂/TiO₂ stacks increases, as seen in FIG. 7B. The result indicates that the compressive strain along the out-of-plain direction is kept in the TZTn samples, which is in sharp contrast to the strain relaxation in the ZO samples (FIG. 6B), when the thickness of the main layer is scaled up. The compressive strain in the TZTn sample may arise from the chemical pressure effect due to the substitution of Zr⁴⁺ (radius: 0.84 Å) with smaller Ti⁴⁺ (radius: 0.74 Å) in the ZrO₂ layer,^{26,27} which may result from the interdiffusion between the ZrO₂ and the TiO₂ layers during the fabrication process.²⁷ According to the density functional theory simulation, the substitution of Zr in ZrO₂ with Ti would lead to distortion of the tetragonal unit cell with a large contraction in the a/b axes and a small contraction in the c axis.²⁶ This is consistent with the XRD results of the TZTn samples, where a smaller compressive strain in (002) and a larger compressive strain in (110) plane are present. Therefore, the relaxation of the compressive strain in the ZO sample with the increasing film thickness, as shown in FIG. 6B, can be understood by the absence of the TiO₂ interfacial layers between the ZrO₂ layers in the main layer of the MIM structures. As a result, the introduction of the TiO₂ interfacial layers between the ZrO₂ layers causes the compressive strain to be maintained in the TZTn samples when the film thickness is scaled up. The emergence of the t(002) peak in the TiO₂/ZrO₂/TiO₂ stacks might also be ascribed to the Ti doping into the ZrO₂ layer. The increase of the [002] orientation in the TZTn sample might account for the decrease of the maximum polarization (Pₘₐₓ) with increasing thickness of the main layer in the TZTn sample, as shown in FIG. 4B. Since the [002] orientation of the t-phase is perpendicular to the polar [001] axis of the ferroelectric o-phase in ZrO₂,²⁸ the grain with the [002] orientation would not contribute to the polarization in the t-to-o phase transition. As a result, the increase of the [002] orientation can lead to a decrease of Pₘₐₓ, which gives rise to the decrease of ESD from ˜94 to 80 J/cm³as the main layer thickness increases, as revealed in FIG. 5B.

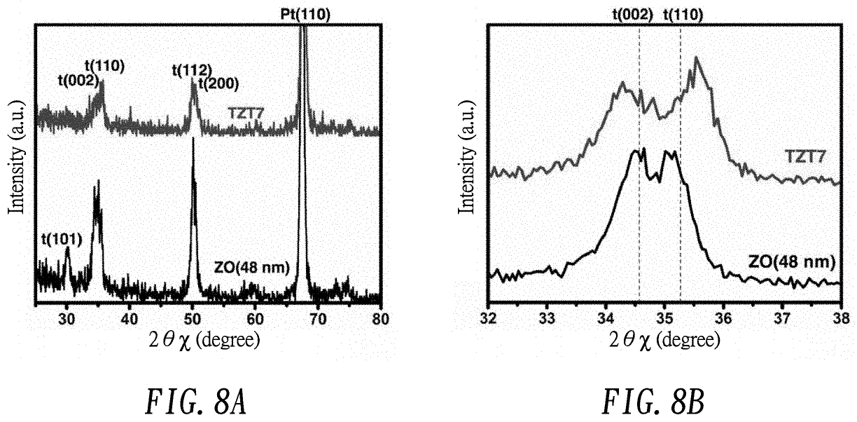

In order to elucidate the type of strain in ZrO₂, an in-plane XRD measurement was carried out. As shown in the wide-range in-plane 2θχ/ϕ XRD patterns in FIG. 8A, the ZO(48 nm) and TZT7 samples present the diffraction peaks from the planes orthogonal to those observed in the out-of-plane XRD. FIG. 8B shows the t(002) and t(110) peaks in the short-range in-plane 2θχ/ϕ XRD patterns of the ZO(48 nm) and TZT7 samples. The ZO(48 nm) sample is nearly free of strain because there are only slight deviations of the t(002) and t(110) diffraction peaks from the reference positions. On the other hand, the compressive and tensile strains develop along the in-plane [110] and [002] directions, respectively, in the TZT7 sample, as observed from the shift of the corresponding diffraction peaks. The compression of the {110} family of planes in both the in-plane and out-of-plane directions in the TZT7 sample, as revealed in FIGS. 7(b) and 8(b), supports the deduction in the above paragraph that the lattice distortion is caused by the substitutional doping of Ti into ZrO₂. In principle, the strain in the {110} planes of tetragonal ZrO₂ caused by the substitutional doping should be the same.²⁶ However, the deviation of the t(110) peak from the reference one at 35.27° in FIG. 7B is greater than that in FIG. 8B, indicating that the compressive strain in the out-of-plane direction is larger than that in the in-plane direction. The result suggests the presence of an in-plane biaxial tensile stress in the film. As a result, the shift of the t(002) peak from the reference one at 34.57° in the TZT7 sample (FIG. 8B) may result from the in-plane biaxial tensile stress. This in-plane biaxial tensile stress may arise from the crystallization process,²⁹ thermal stress,³⁰ or crystallite coalescence during the film growth.³¹

The slim hysteresis loop in the TZTn capacitors, as shown in FIG. 4B, is attributable to the presence of the compressive stress in the ZrO₂ layers. The reduction of hysteresis in AFE materials due to the compressive stress can be understood qualitatively according to the Landau-Ginzburg-Devonshire model, where the free energy U is expanded in terms of the polarization P:

U=1/2α₀(T−T₀)P²+1/4βP⁴+1/6γP⁶−QσP²−P·E (6)

where α₀, β, and γ are the Landau coefficients, E, T, and T₀ are the electric field, temperature, and Curie-Weiss temperature, respectively, Q is the electrostrictive coefficient, and σ is the stress.^{32,33} The free energy is minimal at equilibrium (dU/dP=0), which gives

E=α₀(T−T₀)P+βP³+γP⁵−QσP (7)

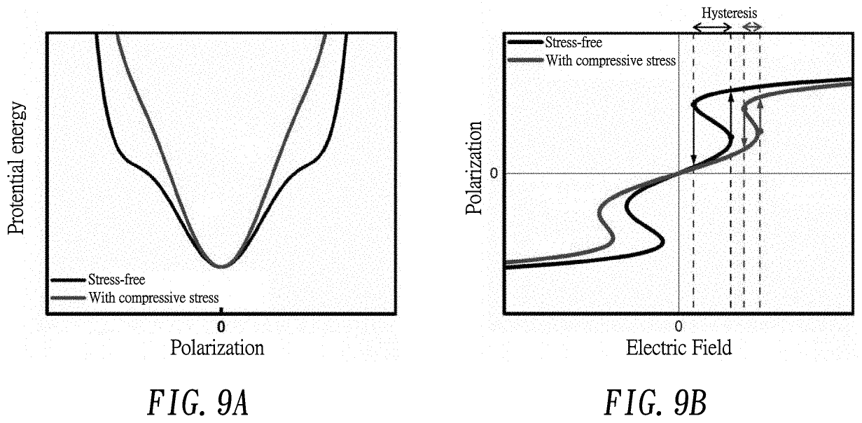

As a result, the P-E relationship can be obtained from equation (7). For the TZTn samples, Q is positive for ZrO₂ and σ is negative according to the XRD patterns.^{9,34} The phenomenological energy landscapes (U-P curves) and P-E curves of an AFE ZrO₂ with and without the presence of the compressive stress are qualitatively compared in FIGS. 9A and 9B. It can be observed that the presence of compressive stress leads to a reduction of the hysteresis in the P-E loop (FIG. 9B). As a result, the compressive stress due to the chemical pressure induced by the Ti doping into ZrO₂ may account for the suppression of the hysteresis loops in the TZTn capacitors.

The improved energy storage performance of the TZTn samples may not result from the compressive chemical pressure alone. Previous studies have reported that the doping of Ti can lead to the stabilization of the t-phase in ZrO₂,^{26,35} which gives rise to an increase of the AFE forward and backward switching fields due to the increase of the energy difference between the t- and o-phases.^{17,35} Notice that the increase of the backward switching fields is beneficial to an increase of the ESD (please refer to FIG. 2). Therefore, the enhancement of the ESD in the TZTn capacitor can be ascribed to the compressive chemical pressure and the stabilization of the t-phase due to the Ti doping into the ZrO₂ layer.

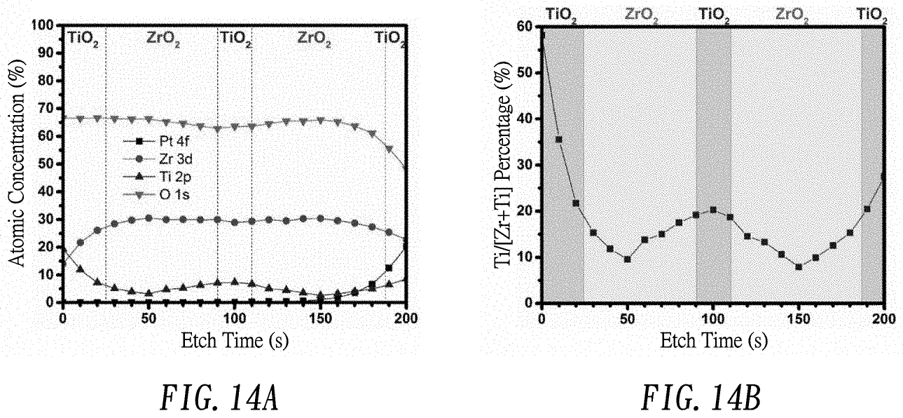

Since the doping of Ti in the TZTn samples arises from the Ti diffusion from the TiO₂ interfacial layers into ZrO₂, a non-uniform doping profile is expected. The doping percentage of Ti in the ZrO₂ layer is investigated by an XPS depth profile analysis. FIG. 14A shows the depth profile of the chemical composition in the TZT2 sample. The O/[Zr+Ti] ratio in the ZrO₂ layer is in the range of 1.8˜1.99, which is near the stoichiometry of the oxides. The depth profile of the Ti/[Zr+Ti] percentage is shown in FIG. 14B, which reveals that the doping percentage of Ti in the ZrO₂ layer approximately ranges from 7.9 to 18.6% and the average doping percentage is around 13.7%.

The chemical composition of the sample was analyzed by an X-ray Photoelectron Spectroscopy (XPS, Thermo Fisher Scientific Theta Probe) with an Al Kα X-ray source (1486.6 eV). Argon ions were used as the sputtering source for the depth profile analysis. The probing depth of the XPS is around 3˜7 nm.

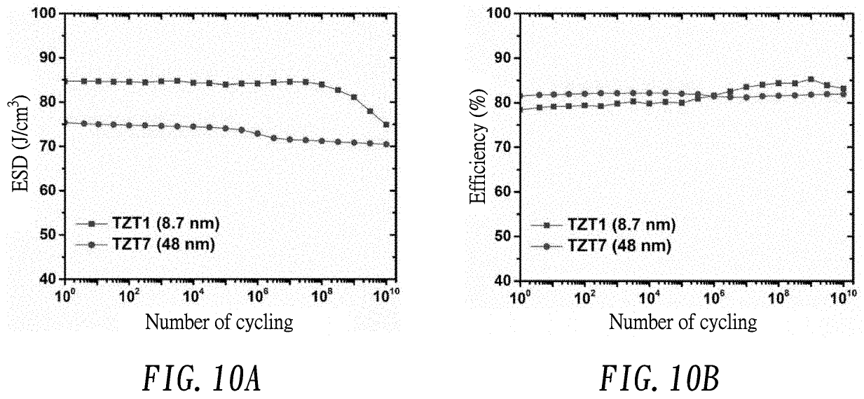

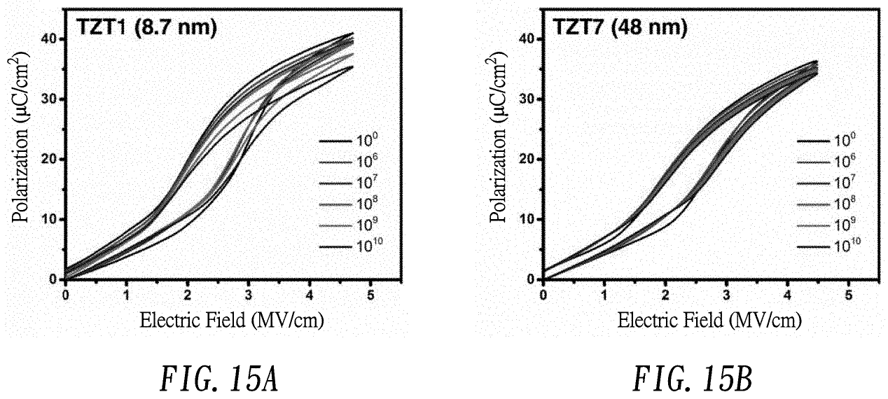

In addition to the high ESD and efficiency, the resistance against the degradation caused by the charging-discharging cycling and the capability of surviving in high-temperature environments are also essential for the practical use of energy storage capacitors. As a result, endurance and thermal stability tests were also carried out to analyze the reliability of the TZTn capacitors. FIG. 10A and 10B show the evolution of the ESD and the efficiency of the TZT1 and TZT7 samples, respectively, with the charging-discharge operation cycles. Their P-E characteristics at different fatigue cycles are provided in FIGS. 15A and 15B, which respectively show evolution of the P-E curves of the TZT1 and TZT7 capacitors with the fatigue cycling of unipolar rectangular pulses of 4.5 MV/cm at a frequency of 125 kHz. The TZT1 and TZT7 capacitors exhibit high endurance with only 12% and 8% reduction of ESD, respectively, after 10¹⁰ operation cycles. A high efficiency of ˜80% is also retained in the TZT1 and TZT7 capacitors throughout the fatigue cycling.

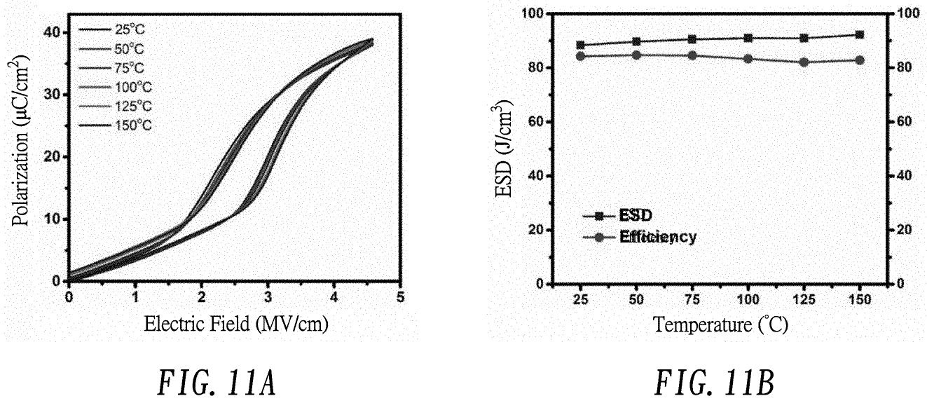

The temperature dependence (from 25° C. to 150° C.) of the P-E curve, ESD, and efficiency for the TZT1 sample is shown in FIGS. 11A and 11B. The result demonstrates the good thermal stability of the TZT1 capacitor, with the ESD and the efficiency kept at ˜90 J/cm³ and ˜83%, respectively, as the temperature increases to 150° C. In addition, it can be observed in the P-E curves in FIG. 11A that the AFE forward and backward switching fields increase slightly with increasing temperature, which is consistent with the previous reports where the same phenomenon has been observed.^{8,13,17,36,37} The increase of the backward switching field leads to an increase in ESD (please refer to FIG. 2). The increase of the forward and backward switching fields with increasing temperature can be understood from both the Landau phase transition theory and the phase stability of ZrO₂. Regarding the Landau theory, the temperature increase means that the AFE material is at a temperature further above the Curie-Weiss temperature, which would give rise to the increase of AFE switching fields according to equations (6) and (7). From the viewpoint of the phase stability of ZrO₂, the t-phase has higher entropy compared to that of the FE o-phase according to first-principles calculations.²⁸ As a result, the t-phase becomes more stable at higher temperatures relative to the FE o-phase; hence a higher electric field is required to induce the phase transformation into the FE o-phase at a higher temperature.^{17,28}

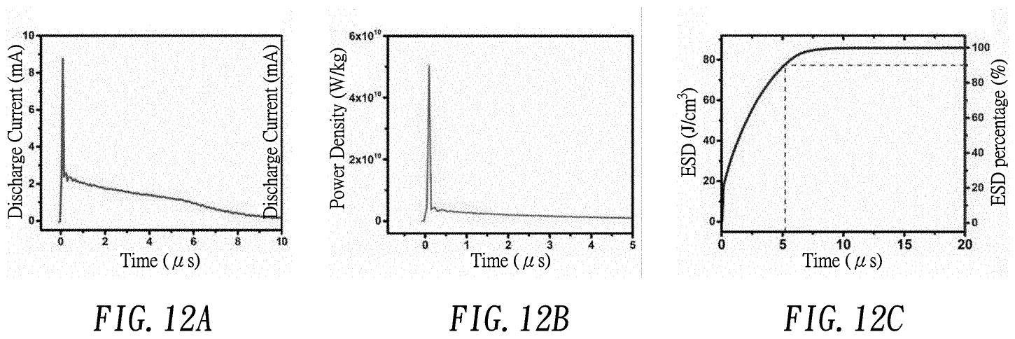

Since energy storage capacitors are commonly used in pulsed-power systems, the time dependence of the discharge and the power density of the TZT1 sample were also investigated. FIGS. 12A-C show the evolution of the discharging current I, the power density, and the ESD and ESD percentage of the TZT1 capacitor over time, respectively. The power density W (per unit mass) is calculated according to

$$W = \frac{{I}^{2} \times R}{( film volume ) \times ρ} \qquad ( 8 )$$

where the resistance R includes the internal resistance (100Ω) of the Keithley 4200 analyzer and the load resistance (1 kΩ) connected in series with the TZT1 sample, and p is the density of the ZrO₂ (6.16 g/cm³).³⁸ The ESD can be obtained by integrating the power density over time. The discharge time is defined as the period during which 90% of the stored energy is released. The results reveal that the TZT1 capacitor possesses a high maximum power density of ˜5×10¹⁰ W/kg and a short discharging time of 5.22 μs, which is favorable in the applications that need high power delivery.

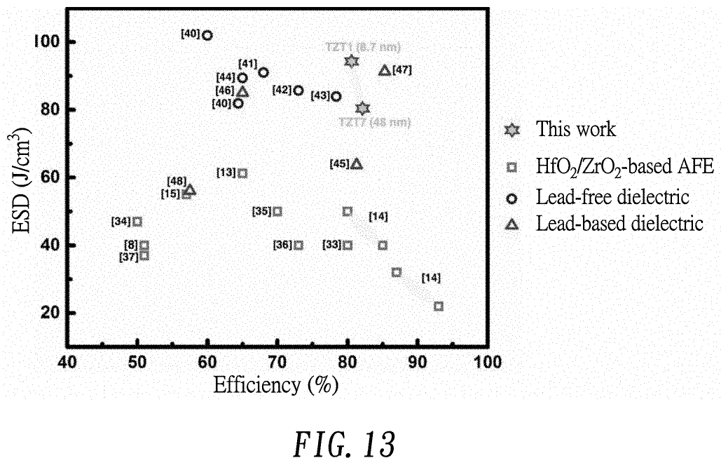

The ESDs and efficiencies of the HfO₂/ZrO₂-based AFE^{8,13-17,36,37,39} and other lead-free⁴⁰⁻⁴⁴/lead-based⁴⁵⁻⁴⁸ dielectric films from the literature are listed in the benchmark in FIG. 13. It should be noted that the ESD of the 3D capacitor is not listed in this benchmark,¹⁵ which demonstrates a significant enhancement of ESD from 37 J/cm³ to 937 J/cm³ per projected 2D capacitor area by building a 3D capacitor in a deep-trench structure.¹⁵ It can be seen that the energy storage performance of the TZTn capacitors is distinguished as compared to those of the lead-based and lead-free dielectric films. Moreover, the ESDs (in the range of 80-94 J/cm³) of the TZTn samples in this disclosure is by far the highest value among the HfO₂/ZrO₂-based AFE thin films. These high ESDs, which are approximated to be 3.6-4.2 Wh/kg (with the film density taken as 6.16 g/cm³),³⁸ are comparable to that of the typical electrochemical supercapacitors (0.05-10 Wh/kg) according to Ragone plot.¹³ The high ESD and the high power density of the TZTn capacitor make it ideal for the applications that require a large amount of energy being stored and released in a fairly short time.^{49,50} Furthermore, the ˜80% efficiency of the TZTn capacitors is also adequate in the benchmark. This result manifests that the introduction of TiO₂ interfacial layers is an effective and practical approach to improve the energy storage performance of the ZrO₂-based thin film supercapacitors.

In the exemplary example of this disclosure, the AFE TiO₂/ZrO₂/TiO₂ stacked structures were investigated to enhance the ESD and the efficiency of energy storage capacitors. The doping of TiO₂ produces a compressive strain in the ZrO₂ layers, which reduces the hysteresis and thus improves the energy storage performance. As a result, high ESD, efficiency, and power density were achieved in the TiO₂/ZrO₂/TiO₂ single-stacked capacitor along with well-behaved endurance and thermal stability. By stacking the TiO₂/ZrO₂/TiO₂ structure, the film thickness is capable of being scaled up with little degradation of the energy storage characteristics, giving rise to an increase of the total energy stored in the film. The improvement is attributed to the increase of electrical breakdown strength due to the blocking of the electrical-tree growth by the ZrO₂/TiO₂ interfaces. Hence the exemplary example demonstrates that the AFE TiO₂/ZrO₂/TiO₂ stacked structures possess the advantages of high ESD, high efficiency, and high power density together with good scalability, which can be a very promising solid-state supercapacitor for high-power electronics, miniaturized energy-autonomous systems, and portable devices for Internet of Things in the near future.

Although specific embodiments have been illustrated and described, it will be appreciated by those skilled in the art that various modifications may be made without departing from the scope of the present invention, which is intended to be limited solely by the appended claims.

What is claimed is:

1. An antiferroelectric capacitor, comprising:
a first electrode;
a main layer formed on the first electrode; and
a second electrode formed on the main layer;
wherein the main layer comprises one or more antiferroelectric layers and a plurality of interfacial layers, and wherein each of the one or more antiferroelectric layers is sandwiched between two of the plurality of interfacial layers.

2. The antiferroelectric capacitor as recited in claim 1, wherein each antiferroelectric layer is made of a material selected from the group consisting of ZrO₂, HfO₂, and Hf₂Zr₁₋ₓO₂, where x denotes a fraction.

3. The antiferroelectric capacitor as recited in claim 2, wherein each antiferroelectric layer is further doped with one or more elements selected from the group consisting of Si, Y, Al, La, Gd, N, Ti, Mg, Sr, Ce, Sn, Ge, Fe, Ta, Ba, Ga, In, and Sc.

4. The antiferroelectric capacitor as recited in claim 1, wherein each interfacial layer is made of an oxide of Si, Y, Al, La, Gd, N, Ti, Mg, Sr, Ce, Sn, Ge, Fe, Ta, Ba, Ga, In, or Sc.

5. The antiferroelectric capacitor as recited in claim 1, wherein the antiferroelectric capacitor has an efficiency more than 80%.

6. The antiferroelectric capacitor as recited in claim 5, wherein the efficiency keeps at more than 80% when a temperature of the antiferroelectric capacitor increases to 150° C.

7. The antiferroelectric capacitor as recited in claim 5, wherein the efficiency keeps at more than 80% after 10¹⁰ cycles of unipolar pulses applied to the antiferroelectric capacitor.

8. The antiferroelectric capacitor as recited in claim 1, wherein a compressive strain along the out-of-plain direction of the antiferroelectric capacitor is kept when the thickness of the main layer is scaled up.

9. The antiferroelectric capacitor as recited in claim 8, wherein the compressive strain in the out-of-plane direction is larger than that in the in-plane direction of the antiferroelectric capacitor.

10. The antiferroelectric capacitor as recited in claim 1, wherein an in-plane biaxial tensile stress exists in the main layer.

11. The antiferroelectric capacitor as recited in claim 1, wherein the antiferroelectric capacitor has an energy storage density (ESD) more than 80 J/cm³.

12. The antiferroelectric capacitor as recited in claim 11, wherein the energy storage density (ESD) is about 90 J/cm³.

13. The antiferroelectric capacitor as recited in claim 12, wherein the energy storage density (ESD) keeps at about 90 J/cm³ when a temperature of the antiferroelectric capacitor increases to 150° C.

14. The antiferroelectric capacitor as recited in claim 12, wherein the energy storage density (ESD) keeps at about 90 J/cm³ after 10¹⁰ cycles of unipolar pulses applied to the antiferroelectric capacitor.

15. The antiferroelectric capacitor as recited in claim 1, wherein an interdiffusion occurs between the one or more antiferroelectric layers and the plurality of interfacial layers during a fabrication process of the antiferroelectric capacitor.

16. The antiferroelectric capacitor as recited in claim 1, wherein a thickness of the main layer is about 48 nm.

17. The antiferroelectric capacitor as recited in claim 1, wherein the antiferroelectric capacitor possesses a power density about 5×10¹⁰ W/kg.

18. The antiferroelectric capacitor as recited in claim 1, wherein the antiferroelectric capacitor has a discharging time of 5.22 μs.

19. The antiferroelectric capacitor as recited in claim 1, wherein the first electrode and the second electrode are made of a conductive material selected from the group consisting of Pt, W, TiN, Ti, Ir, Ru, RuOx, Cr, Ni, Au, Ag, and Al.
